(19) United States
(12) Patent Application Publication
(10) Pub. No.: US 2026/0221212 A1
(43) Pub. Date: Jul. 30, 2026

(54) METHOD, SYSTEM, DEVICE, AND STORAGE MEDIUM FOR DETERMINING WCK-ON VALUE OF LPDDR CHIP

(71) Applicant: Shenzhen Rayson Technology Co., Ltd., Shenzhen (CN)

(72) Inventor: Zi Liu, Shenzhen (CN)

(21) Appl. No.: 19/403,888

(22) Filed: Nov. 30, 2025

(30) Foreign Application Priority Data
Jan. 22, 2025 (CN) 202510102669X

(51) Int. Cl. G11C 29/14; G11C 29/12; G11C 29/38

(52) U.S. Cl. CPC G11C 29/14; G11C 29/12015; G11C 29/38

(57) ABSTRACT

This disclosure discloses a method, a system, a device, and storage medium for determining the WCK-ON value of an LPDDR chip. The method comprises: acquiring a first MR (Mode Register) value of the LPDDR chip; acquiring a second MR value of the LPDDR chip; comparing the first MR value and the second MR value respectively with a preset MR value to obtain a first comparison result; determining a first CHS (Channel Selection) mode based on the first MR value and the second MR value, and then determining a first WCK-ON value of the LPDDR chip according to the first CHS mode; modifying the second MR value to the first MR value, determining a second CHS mode based on the second MR value, and then determining a second WCK-ON value of the LPDDR chip according to the second CHS mode.

### TECHNICAL FIELD

The present disclosure relates to the field of memory testing technology, and particularly to a method, a system, a device, and storage medium for determining the WCK-ON value of an LPDDR chip.

### BACKGROUND

LPDDR (Low-Power Double Data Rate Synchronous Dynamic Random-Access Memory) is a type of memory used in electronic devices with stringent power consumption requirements, such as mobile devices and IoT (Internet of Things) devices. It meets the device's demands for memory capacity and performance while significantly reducing power consumption, thereby extending the device's battery life.

Existing LPDDR chips are typically designed with either a dual-channel architecture or a single-channel architecture. That is, an LPDDR chip may include two channels (i.e., dual Rank) or one channel (i.e., single Rank). Before initialization, an LPDDR chip needs to obtain the WCK-ON (Write Clock-ON) value, and then initialize the LPDDR chip based on this value. However, there is currently a lack of a universal solution that can simultaneously accommodate the acquisition of WCK-ON for both single-Rank and dual-Rank configurations. When dealing with LPDDR chips with different Rank configurations, separate initialization schemes must be developed for single-Rank and dual-Rank setups to obtain the WCK-ON value and perform initialization. This not only increases testing costs but also raises the likelihood of errors due to scheme switching, thereby reducing the accuracy of determining the WCK-ON value.

### SUMMARY

In view of this, the objective of the embodiments of the present disclosure is to provide a method, a system, a device, and storage medium for determining the WCK-ON value of an LPDDR chip that can simultaneously accommodate both single-Rank and dual-Rank LPDDR chips, accurately test the WCK-ON value of the LPDDR chip, and achieve low testing costs.

In a first aspect, the embodiments of the present disclosure provide a method for determining the WCK-ON value of an LPDDR chip, which includes:

acquiring a first MR value of the LPDDR chip, wherein the first MR value represents the first configuration information corresponding to the first Rank;

acquiring a second MR value of the LPDDR chip, wherein the second MR value represents the second configuration information corresponding to the second Rank;

comparing the first MR value and the second MR value respectively with a preset MR value to obtain a first comparison result.

In a scenario where the first comparison result indicates that the first MR value and/or the second MR value is equal to the preset MR value and the second MR value is updated, a first CHS mode is determined based on the first MR value and the second MR value, and then a first WCK-ON value of the LPDDR chip is determined according to the first CHS mode. The first CHS mode indicates that the LPDDR chip has dual Ranks and includes the first synchronization coordination information between the Ranks.

In a scenario where the first comparison result indicates that the second MR value is not updated, the second MR value is corrected to the first MR value, a second CHS mode is determined based on the second MR value, and then a second WCK-ON value of the LPDDR chip is determined according to the second CHS mode. The second CHS mode indicates that the LPDDR chip has a single Rank and includes the second synchronization coordination information between the Ranks.

In some optional embodiments, the step of determining, when the first comparison result indicates that the first MR value and/or the second MR value is equal to the preset MR value and the second MR value is updated, the first CHS mode based on the first MR value and the second MR value, comprises:

configuring the LPDDR chip in a dual-Rank mode when the first comparison result indicates that the first MR value is equal to the preset MR value and/or the second MR value is equal to the preset MR value, and the second MR value is updated;

acquiring a first synchronization coordination table corresponding to the dual-Rank mode;

determining the first CHS mode based on the first synchronization coordination table, the first MR value, and the second MR value.

In some optional embodiments, the step of determining the first CHS mode based on the first synchronization coordination table, the first MR value, and the second MR value, comprises:

determining the first configuration information and the second configuration information based on the first MR value, the second MR value, and a preset configuration table;

determining first synchronization coordination information based on the first configuration information and the second configuration information;

searching for a first entry in the first synchronization coordination table that matches the first synchronization coordination information;

configuring the CHS mode corresponding to the first entry as the first CHS mode.

In some optional embodiments, the method further comprises:

configuring the first CHS mode as a first mode and configuring the first WCK-ON value as a first numerical value according to the first mode, when the first comparison result indicates that the first MR value is not equal to the preset MR value, the second MR value is not equal to the preset MR value, and the second MR value is updated;

configuring the first CHS mode as a second mode and configuring the first WCK-ON value as a second numerical value according to the second mode, when the first comparison result indicates that the first MR value and/or the second MR value is equal to the preset MR value and the second MR value is updated.

In some optional embodiments, the step of determining the second CHS mode based on the second MR value and determining the second WCK-ON value of the LPDDR chip according to the second CHS mode, comprises:

configuring the second CHS mode as the second mode and configuring the second WCK-ON value as the second numerical value according to the second mode, when the second MR value is equal to the preset MR value;

configuring the second CHS mode as the first mode and configuring the second WCK-ON value as the first numerical value according to the first mode, when the second MR value is not equal to the preset MR value.

In some optional embodiments, the step of determining the second CHS mode based on the second MR value and determining the second WCK-ON value of the LPDDR chip according to the second CHS mode, comprises:

configuring the second CHS mode as the second mode and configuring the second WCK-ON value as the second numerical value according to the second mode, when the second MR value is equal to the preset MR value;

configuring the second CHS mode as the first mode and configuring the second WCK-ON value as the first numerical value according to the first mode, when the second MR value is not equal to the preset MR value.

In some optional embodiments, the step of determining the second CHS mode based on the second synchronization coordination table and the second MR value, comprises:

determining second synchronization coordination information based on the second MR value and a preset configuration table;

searching for a second entry in the second synchronization coordination table that matches the second synchronization coordination information;

configuring the CHS mode corresponding to the second entry as the second CHS mode.

In a second aspect, an embodiment of the present disclosure provides a system for determining the WCK-ON value of an LPDDR chip, comprising:

a first module configured to acquire a first MR value of the LPDDR chip, wherein the first MR value represents first configuration information corresponding to a first Rank;

a second module configured to acquire a second MR value of the LPDDR chip, wherein the second MR value represents second configuration information corresponding to a second Rank;

a third module configured to compare the first MR value and the second MR value respectively with a preset MR value to obtain a first comparison result;

a fourth module configured to, when the first comparison result indicates that the first MR value and/or the second MR value is equal to the preset MR value and the second MR value is updated, determine a first CHS mode based on the first MR value and the second MR value, and determine a first WCK-ON value of the LPDDR chip according to the first CHS mode, wherein the first CHS mode indicates that the LPDDR chip has dual Ranks and includes first synchronization coordination information between the Ranks;

a fifth module configured to, when the first comparison result indicates that the second MR value is not updated, correct the second MR value to the first MR value, determine a second CHS mode based on the second MR value, and determine a second WCK-ON value of the LPDDR chip according to the second CHS mode, wherein the second CHS mode indicates that the LPDDR chip has a single Rank and includes second synchronization coordination information between the Ranks.

In a third aspect, an embodiment of the present disclosure provides a memory testing device applicable to a smart card, the device comprising:

at least one processor;

at least one memory configured to store at least one program;

wherein when the at least one program is executed by the at least one processor, it enables the at least one processor to implement the method as described above.

In a fourth aspect, an embodiment of the present disclosure provides a computer-readable storage medium storing a processor-executable program, which, when executed by a processor, is configured to perform the method as described above.

Implementing the embodiments of the present disclosure offers the following advantageous effects. The embodiment of the present disclosure provides a method for determining the WCK-ON value of an LPDDR chip, comprising: acquiring a first MR value of the LPDDR chip, wherein the first MR value represents first configuration information corresponding to a first Rank; acquiring a second MR value of the LPDDR chip, wherein the second MR value represents second configuration information corresponding to a second Rank; comparing the first MR value and the second MR value respectively with a preset MR value to obtain a first comparison result; when the first comparison result indicates that the first MR value and/or the second MR value is equal to the preset MR value and the second MR value is updated, determining a first CHS mode based on the first MR value and the second MR value, and determining a first WCK-ON value of the LPDDR chip according to the first CHS mode, wherein the first CHS mode indicates that the LPDDR chip has dual Ranks and includes first synchronization coordination information between the Ranks; when the first comparison result indicates that the second MR value is not updated, correcting the second MR value to the first MR value, determining a second CHS mode based on the second MR value, and determining a second WCK-ON value of the LPDDR chip according to the second CHS mode, wherein the second CHS mode indicates that the LPDDR chip has a single Rank and includes second synchronization coordination information between the Ranks. By acquiring the first MR value and the second MR value of the first Rank and the second Rank, comparing them with the preset MR value, determining whether the LPDDR chip has dual Ranks or a single Rank, and determining the corresponding first WCK-ON value and second WCK-ON value, the method can simultaneously accommodate both dual-Rank and single-Rank LPDDR chips for determining the WCK-ON value. There is no need to formulate different initialization schemes for single-Rank and dual-Rank chips, resulting in low testing costs, reduced probability of errors due to scheme switching, and improved accuracy in determining the WCK-ON value.

### BRIEF DESCRIPTION OF THE DRAWINGS

FIG. 1 is a schematic flow diagram illustrating the steps of a method for determining the WCK-ON value of an LPDDR chip provided in an embodiment of the present disclosure;

FIG. 2 is a schematic diagram showing a first Rank and a second Rank of an LPDDR chip provided in an embodiment of the present disclosure;

FIG. 3 is a structural block diagram of a system for determining the WCK-ON value of an LPDDR chip provided in an embodiment of the present disclosure; and

FIG. 4 is a structural block diagram of a memory testing device provided in an embodiment of the present disclosure.

### DETAILED DESCRIPTION

In order to make the objectives, technical solutions, and advantages of the present disclosure clearer and more understandable, the present disclosure is further elaborated in detail below in conjunction with the accompanying drawings and embodiments. It should be understood that the specific embodiments described herein are merely used to explain the present disclosure and are not intended to limit it.

It should be noted that although functional modules are divided in the device schematic diagrams and logical sequences are shown in the flowcharts, in certain cases, the steps illustrated or described may be executed in a sequence different from the module division in the device or the sequence in the flowcharts. The terms "first," "second," etc., in the specification, claims, or the aforementioned drawings are used to distinguish similar objects and are not necessarily used to describe a specific order or sequence.

An embodiment of the present disclosure provides a method for determining the WCK-ON value of an LPDDR chip, which includes: acquiring a first MR value of the LPDDR chip, where the first MR value represents the first configuration information corresponding to the first Rank; acquiring a second MR value of the LPDDR chip, wherein the second MR value represents the second configuration information corresponding to the second Rank; comparing the first MR value and the second MR value respectively with a preset MR value to obtain a first comparison result; when the first comparison result indicates that the first MR value and/or the second MR value is equal to the preset MR value and the second MR value is updated, determining a first CHS mode based on the first MR value and the second MR value, and determining a first WCK-ON value of the LPDDR chip according to the first CHS mode, wherein the first CHS mode indicates that the LPDDR chip has dual Ranks and includes first synchronization coordination information between the Ranks; when the first comparison result indicates that the second MR value is not updated, correcting the second MR value to the first MR value, determining a second CHS mode based on the second MR value, and determining a second WCK-ON value of the LPDDR chip according to the second CHS mode, wherein the second CHS mode indicates that the LPDDR chip has a single Rank and includes second synchronization coordination information between the Ranks. By acquiring the first MR value and the second MR value of the first Rank and the second Rank and comparing them with the preset MR value, it is determined whether the LPDDR chip has dual Ranks or a single Rank, and the corresponding first WCK-ON value and second WCK-ON value are determined accordingly. This allows for simultaneous compatibility with both dual-Rank and single-Rank LPDDR chips for determining the WCK-ON value, eliminating the need for formulating different initialization schemes for single-Rank and dual-Rank chips, resulting in low testing costs, reduced probability of errors due to scheme switching, and improved accuracy in determining the WCK-ON value.

The present disclosure is further elaborated below in conjunction with the accompanying drawings.

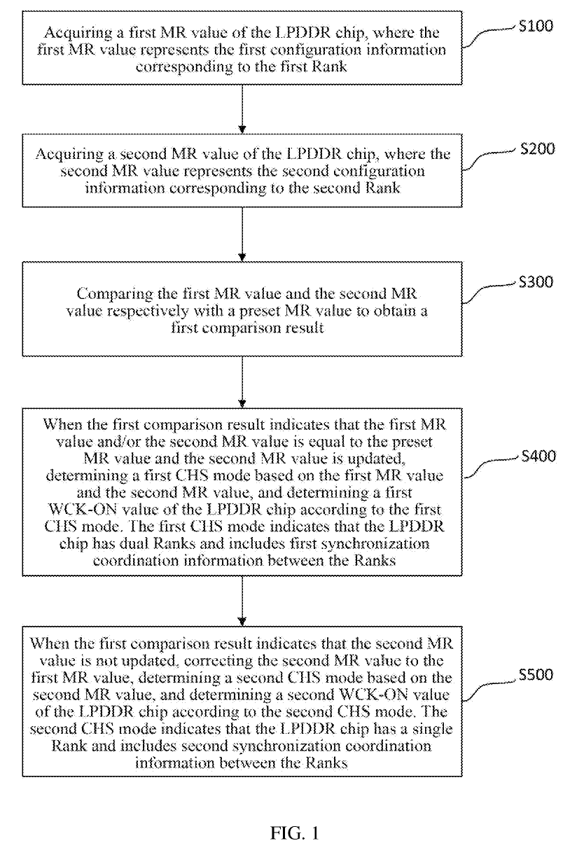

As shown in FIG. 1, an embodiment of the present disclosure provides a method for determining the WCK-ON value of an LPDDR chip, which includes the following steps;

S100: acquiring a first MR value of the LPDDR chip, wherein the first MR value represents the first configuration information corresponding to the first Rank;

S200: acquiring a second MR value of the LPDDR chip, wherein the second MR value represents the second configuration information corresponding to the second Rank;

S300: comparing the first MR value and the second MR value respectively with a preset MR value to obtain a first comparison result;

S400: when the first comparison result indicates that the first MR value and/or the second MR value is equal to the preset MR value and the second MR value is updated, determining a first CHS mode based on the first MR value and the second MR value, and determining a first WCK-ON value of the LPDDR chip according to the first CHS mode; wherein the first CHS mode indicates that the LPDDR chip has dual Ranks and includes first synchronization coordination information between the Ranks;

S500: when the first comparison result indicates that the second MR value is not updated, correct the second MR value to the first MR value, determining a second CHS mode based on the second MR value, and determining a second WCK-ON value of the LPDDR chip according to the second CHS mode; wherein the second CHS mode indicates that the LPDDR chip has a single Rank and includes second synchronization coordination information between the Ranks.

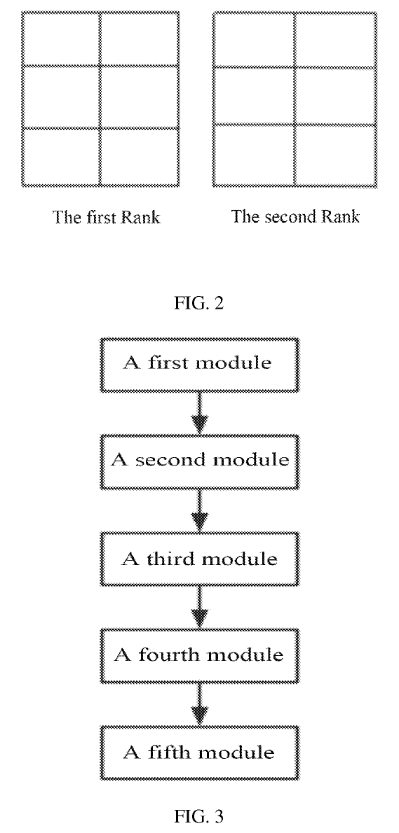

Specifically, referring to FIG. 2, in an LPDDR chip (this application takes LPDDR4/5 as an example), the MR (Mode Register) value plays a crucial role. It stores the configuration information for each Rank (memory channel) within the LPDDR chip. Here, the first MR value corresponds to the first configuration information of the first Rank, and the second MR value corresponds to the second configuration information of the second Rank. This configuration information covers multiple aspects, such as operating modes (different operational settings like high-performance mode, low-power mode, etc.), timing parameters for data transmission (including clock signal timing for read and write operations, data retention time, etc.), address mapping methods (determining the correspondence between the storage locations of data in the memory channels and external addresses), and relevant settings for collaborative work with other components. The specific configuration information is not limited herein. By acquiring the first MR value and the second MR value, the specific current configuration states of the first Rank and the second Rank can be determined.

The preset MR value is a reference value pre-set based on factors such as the standard specifications of the LPDDR chip, conventional best practices, and design expectations, such as 0XFFFF. The specific value is set according to actual requirements and is not limited herein. The preset MR value conforms to the configuration state required for the normal and stable operation of the chip. For example, in common application scenarios where dual Ranks work collaboratively or a single Rank operates independently, there is a default, verified configuration state. The MR value corresponding to this state is set as the preset MR value. By comparing with it, it can be quickly determined whether the actual first MR value and second MR value are within the expected reasonable range and whether corresponding adjustments or further acquisition of the WCK-ON value for initialization are required.

The first MR value and the second MR value are compared one-to-one with the preset MR value. For example, compare whether the data bits for the operating mode are the same, whether the timing parameter bits are consistent, etc., or compare the overall data bits one by one. The specific comparison method is not limited herein. The first comparison result can present various situations, such as the first MR value being equal to the preset MR value while the second MR value is not, or both being equal to the preset MR value, or both not being equal, etc.

When the first comparison result shows that the first MR value and/or the second MR value is equal to the preset MR value and the second MR value is updated, it means that the initial configuration of at least one Rank conforms to conventional expectations, while the second Rank has undergone new configuration changes, indicating that the LPDDR chip is operating in dual-Rank mode (with dual Ranks) and the first WCK-ON value for the dual Ranks of the LPDDR chip is normal. Initialization of the LPDDR chip can be carried out or completed as required.

The first CHS (Channel Synchronization) mode is determined based on both the first MR value and the second MR value because the configurations of both Ranks have an impact on the synchronization coordination between the dual Ranks. For example, certain parameters in the first MR value may specify some characteristics of the first Rank in terms of data transmission (such as data transmission priority, acceptable clock delay range, etc.), while the updated parts in the second MR value reflect new requirements or changes of the second Rank (such as changes in data width or read-write order, etc.). These pieces of information need to be integrated to determine the coordination method between the dual Ranks. Through a mapping relationship between the configuration information and the CHS mode, key configuration parameters extracted from the first MR value and the second MR value are matched according to this mapping relationship to determine the first CHS mode. This mode provides detailed instructions on the first synchronization coordination information between Ranks in the dual-Rank state of the LPDDR chip, such as specifying the clock synchronization method between the two Ranks (whether it is strict frequency and phase synchronization or whether a certain phase difference is allowed), the sequence of data strobing, and some interaction rules during data transmission.

The first WCK-ON value is determined based on the determined first CHS mode because the WCK-ON value (write clock enable value) is closely related to the synchronization coordination between Ranks. In dual-Rank mode, to ensure that data can be accurately written simultaneously into the memory cells corresponding to the two Ranks, the first WCK-ON value needs to be precisely set according to the synchronization coordination requirements specified by the first CHS mode. For example, if the first CHS mode requires strict clock synchronization and data to be written at a specific clock edge, then the first WCK-ON value must be precisely set to the specific time point within the corresponding clock cycle to ensure that the write clock signal is enabled at the correct moment, enabling the two Ranks to collaboratively complete the data write operation. If the first CHS mode allows a certain clock phase difference and a relatively enoughrelaxed data write time window, the range of values for the first WCK-ON value will be adjusted accordingly, but it still needs to meet the accuracy and synchronization requirements for data write in dual Ranks. The first WCK-ON value is represented by binary code, and the specific representation method is not limited herein.

When the first comparison result shows that the second MR value is not updated, it indicates that the second Rank is not enabled or does not exist (i.e., the LPDDR chip is in single-Rank mode at this time). Therefore, assuming that the second Rank is enabled or exists, the second MR value of the virtual second Rank is corrected to the first MR value. In this way, the second WCK-ON value can be determined based on the first MR value of the first Rank itself, following the determination method for dual-Rank mode without affecting the reading of the WCK-ON value for single Rank.

In some embodiments, the process of determining the second CHS mode is as follows. The second CHS mode is determined based on the corrected second MR value (which is now the same as the first MR value). This mode mainly reflects the second synchronization coordination information of the LPDDR chip when it is in single-Rank mode (in fact, it is the coordination situation of the single Rank itself at this time, and the second Rank is a virtual Rank). Since single-Rank operation has different characteristics and requirements in terms of data transmission and clock synchronization compared to collaborative operation of dual Ranks, the corresponding second CHS mode is determined according to the relevant rules and coordination methods during single-Rank operation. For example, in single-Rank mode, data transmission only needs to consider its own read-write timing and internal coordination, without involving synchronization issues with another Rank. The coordination rules for clock signal control, data strobing, etc., are relatively simple and straightforward. The second CHS mode is determined based on these rules and the information of the corrected second MR value.

In some embodiments, the process of determining the second WCK-ON value is as follows. Similarly, the second WCK-ON value is determined based on the determined second CHS mode. In single-Rank mode, the activation time of the write clock mainly focuses on meeting the read-write timing requirements of the Rank itself, without the need to consider synchronization issues with another Rank. Therefore, the determination of the second WCK-ON value places more emphasis on ensuring that data can be accurately and efficiently written into the memory cells within this single Rank. For example, based on parameters such as the read-write speed and data retention time of the single Rank, combined with the coordination rules regarding clock signals and data operations in the second CHS mode, an appropriate second WCK-ON value is calculated or set to ensure the smooth progress of data write operations in single-Rank mode.

In some optional embodiments, the method further includes: when the first comparison result indicates that the first MR value is not equal to the preset MR value, the second MR value is not equal to the preset MR value, and the second MR value is updated, the first CHS mode is configured as the first mode, and the first WCK-ON value is configured as the first numerical value according to the first mode; when the first comparison result indicates that the first MR value and/or the second MR value is equal to the preset MR value and the second MR value is updated, the first CHS mode is configured as the second mode, and the first WCK-ON value is configured as the second numerical value according to the second mode.

Specifically, when the first MR value is not equal to the preset MR value, the second MR value is not equal to the preset MR value, and the second MR value is updated, it indicates that the current configuration information of the first Rank and the second Rank (represented by the first MR value and the second MR value respectively) is inconsistent with the preset standard configuration (preset MR value). However, since the configuration of the second Rank has been updated, it shows that the LPDDR chip has dual Ranks, and the configuration states of the first Rank and the second Rank have deviated from conventional expectations, requiring corresponding initialization. The first CHS mode is configured as the first mode, which can specifically be a low-level signal mode (not specifically limited). The first CHS mode is set to the first mode by writing specific instructions or parameters into relevant control registers within the LPDDR chip. The setting of these instructions and parameters follows the communication protocols and operation specifications stipulated by the chip manufacturer, involving code for specifying mode selection and some related basic parameter settings (such as the approximate range of clock synchronization and the default method of data strobing) to enable the synchronization coordination mechanism under the first mode. Once the first mode is determined, the first WCK-ON value needs to be correspondingly configured as the first numerical value. Specifically, the first WCK-ON value is configured as "0" in the first mode to initialize the LPDDR chip according to the first WCK-ON value.

When the first MR value and/or the second MR value is equal to the preset MR value and the second MR value is updated, it indicates that the configuration of at least one Rank conforms to the preset standard configuration, and at the same time, there is an update in the configuration of the second Rank. Overall, part of the LPDDR chip configuration is in the expected normal state, and the update of the second Rank shows that the LPDDR chip has dual Ranks, and the configuration states of the first Rank and/or the second Rank conform to conventional expectations. The first CHS mode is configured as the second mode, which can specifically be a high-level mode (not specifically limited). The second mode is usually an optimized synchronization coordination mode suitable for scenarios where some Ranks conform to preset standards and there are Rank updates. It fully utilizes the configuration advantages of the Ranks that conform to the standards and combines the updated content of the second Rank to achieve more efficient and precise synchronization coordination between dual Ranks.

After the second mode is determined, the first WCK-ON value needs to be correspondingly configured as the second numerical value, which can specifically be "1" (not specifically limited). According to the second numerical value, selective initialization or exit from initialization of the LPDDR chip can be carried out (not specifically limited here).

In some optional embodiments, determining the second CHS mode based on the second MR value and determining the second WCK-ON value of the LPDDR chip according to the second CHS mode include the following steps: when the second MR value is equal to the preset MR value, the second CHS mode is configured as the second mode, and the second WCK-ON value is configured as the second numerical value according to the second mode; when the second MR value is not equal to the preset MR value, the second CHS mode is configured as the first mode, and the second WCK-ON value is configured as the first numerical value according to the first mode.

Specifically, when the second MR value is equal to the preset MR value, it means that the configuration of the second Rank is in a standard state that conforms to conventional expectations. The second CHS mode is configured as the second mode. When the second MR value is not equal to the preset MR value, it means that the configuration of the second Rank does not conform to the standard state of conventional expectations, and the second CHS mode is configured as the first mode. This enables more accurate and efficient synchronization coordination for the LPDDR chip in either a single-Rank scenario (where the second Rank is a virtual Rank, equivalent to single-Rank operation) or between Ranks (in cases of self-coordination). It achieves the determination of the CHS mode for a single-Rank LPDDR chip and subsequently determines the second WCK-ON value. According to the determination criteria for the LPDDR chip in a dual-Rank scenario, when the first MR and/or the second MR is equal to the preset MR value, the first CHS mode is configured as the second mode. When dealing with a single-Rank scenario, a virtual second Rank is cleverly established, and the second MR value is configured as the first MR value. This allows the determination rules originally designed for dual-Rank scenarios to be applicable to single-Rank scenarios. A unified processing framework is logically constructed, enabling single-Rank and dual-Rank scenarios to follow similar rules in determining configuration parameters (especially the CHS mode and subsequent determination of the WCK-ON value). This reduces the complexity of having to separately design different determination and configuration methods for different operating modes/memory structures (single-Rank or dual-Rank). Therefore, when the LPDDR chip is in a single-Rank mode, by establishing a virtual second Rank and configuring the second MR value as the first MR value, the determination rules for dual-Rank scenarios can be applied to single-Rank scenarios. This enables the simultaneous compatibility of WCK-ON value testing for both single-Rank and dual-Rank LPDDR chips, resulting in low testing costs.

In some optional embodiments, when the first comparison result indicates that the first MR value and/or the second MR value is equal to the preset MR value and the second MR value is updated, determining the first CHS mode based on the first MR value and the second MR value includes the following steps: when the first comparison result indicates that the first MR value is equal to the preset MR value and/or the second MR value is equal to the preset MR value, and the second MR value is updated, configuring the LPDDR chip in the dual-Rank mode; obtaining the first synchronization coordination table corresponding to the dual-Rank mode; determining the first CHS mode based on the first synchronization coordination table, the first MR value, and the second MR value.

Specifically, when the first comparison result shows that the first MR value is equal to the preset MR value and/or the second MR value is equal to the preset MR value, and the second MR value is updated, it means that at least part of the chip's configuration state conforms to conventional expectations (i.e., the configuration of at least one Rank matches the preset standard), while the second Rank has undergone new configuration changes. In this case, the LPDDR chip operates in the dual-Rank mode and needs to coordinate the work between the two Ranks based on their respective states.

The first synchronization coordination table corresponding to the dual-Rank mode is a table that details the synchronization coordination between different Ranks when the LPDDR chip operates in the dual-Rank mode. This table comprehensively records the correspondence between different Rank configuration situations (specifically reflected in different combinations of MR values and different settings of relevant parameters for each Rank) and the specific synchronization coordination mode (i.e., the CHS mode) of the LPDDR chip in the dual-Rank mode. It also covers numerous detailed parameter settings related to the collaborative work of the dual Ranks. For example, the table includes information on the clock synchronization method between Ranks (strict synchronization with the same frequency and phase or synchronization that allows a certain phase difference), the coordination mechanism of data strobe signals (how to ensure accurate data transmission and switching between the two Ranks), the sequence of read and write operations, and the corresponding time interval requirements, among other aspects. It aims to provide comprehensive and precise guidance for achieving efficient and stable data processing in the dual-Rank mode, helping users quickly determine the appropriate synchronization coordination mode and related parameters based on the actual Rank configuration situation.

After obtaining the first synchronization coordination table, it is necessary to determine the first CHS mode based on the current first MR value and second MR value. First, a detailed analysis of each key information bit in the first MR value and the second MR value is conducted, as these information bits carry specific details about the current configurations of the two Ranks. For example, certain specific bits in the first MR value represent information such as the data transmission rate setting, the clock synchronization accuracy requirement, or the read-write operation priority of the first Rank. Similarly, the updated parts of the second MR value also contain key information reflecting the new configuration situation of the second Rank, such as changed data widths, new clock modes, or different address mapping methods. Then, the key configuration information extracted from the first MR value and the second MR value is comprehensively matched and searched against the content of the first synchronization coordination table. According to the correspondence specified in the table, each parameter is carefully compared. When a record is found where all parameters are completely consistent with the key configuration information extracted from the two MR values, the CHS mode corresponding to that record is the first CHS mode that needs to be determined. For example, assuming that the information parsed from the first MR value and the second MR value indicates that the first Rank adopts a high data transmission rate and a relatively loose clock synchronization method, and the updated second Rank has a specific data width and a specific sequence of read-write operations. By searching for a corresponding entry in the first synchronization coordination table that meets these conditions, if the corresponding entry in the table shows that the CHS mode in this case is "asynchronous data transmission, loose clock synchronization (with a phase difference allowance range of ±5 ns), and a specific read-write sequence" mode, then this can be determined as the first CHS mode for the current situation. Subsequently, other key parameters such as the first WCK-ON value that are compatible with this determined first CHS mode can be further determined to ensure that the chip can perform stable data read and write operations according to accurate synchronization coordination rules in the dual-Rank mode.

In some optional embodiments, determining the first CHS mode based on the first synchronization coordination table, the first MR value, and the second MR value, includes the following steps: determining first configuration information and second configuration information according to the first MR value, the second MR value, and a preset configuration table; determining first synchronization coordination information based on the first configuration information and the second configuration information; searching for a first entry in the first synchronization coordination table that matches the first synchronization coordination information; configuring the CHS mode corresponding to the first entry as the first CHS mode.

Specifically, the preset configuration table is a reference table used to parse the specific configuration meanings represented by MR values. It establishes a mapping relationship between each bit or bit segment in the MR values and the actual chip configuration parameters, covering a wide range of configuration information such as operating modes, data transmission rates, clock synchronization methods, and address mapping rules. Through this table, the abstract MR values presented in binary form can be converted into intuitive and understandable specific configuration content, thereby obtaining the detailed configuration situations corresponding to each Rank. For the first MR value, according to the preset configuration table, the specific configuration meanings corresponding to the relevant bit combinations are checked. For example, if, according to the mapping relationship in the preset configuration table, certain binary values represent a data transmission rate of 1600 Mbps per second for the first Rank, and other values indicate that the clock synchronization method it adopts is a loose synchronization mode that allows a certain phase difference, by interpreting bit by bit or segment by segment in this way, the complete first configuration information of the first Rank can be determined, including specific parameter settings related to data read-write, synchronization coordination, and other aspects. Similarly, for the second MR value, it is also parsed according to the preset configuration table. Since the second MR value represents the configuration situation of the second Rank and is updated, the parsed second configuration information will reflect its latest settings, such as changes in the new data width and different read-write sequences. Through the first MR value, the second MR value, and the preset configuration table, the first configuration information and the second configuration information are respectively clarified.

The first configuration information and the second configuration information contain numerous specific parameter settings for each of the two Ranks. The first synchronization coordination information, on the other hand, extracts, from the perspective of the overall collaborative work of the two Ranks, the key content closely related to how they synchronize and coordinate data read-write operations. It comprehensively considers multiple factors such as the differences in clock synchronization requirements between the two Ranks, the interactive methods of data transmission, the sequence of read-write operations, and the guarantee mechanisms for data accuracy and integrity. For example, the first configuration information shows that the first Rank has a relatively fast data transmission rate but relatively loose requirements for clock synchronization accuracy, while the second configuration information indicates that the second Rank has a change in data width and specific requirements for the read-write sequence. Based on these situations, the determined first synchronization coordination information is "the two Ranks adopt an asynchronous data transmission method, clock synchronization allows a certain phase difference, data transmission should be carried out in the order of the second Rank having priority in read-write operations, and a specific verification mechanism is used to ensure data accuracy during transmission." Through such integration and analysis of the configuration information of the two Ranks, the key coordination requirements for their collaborative work, namely the first synchronization coordination information, are sorted out, and a matching entry is searched for in the first synchronization coordination table.

The first synchronization coordination table is a pre-organized table that records the correspondence between different synchronization coordination situations and corresponding CHS modes, covering the synchronization coordination modes corresponding to various possible dual-Rank configuration combinations. The first entry is serched for in this table that matches the first synchronization coordination information to find the specific record entry that meets the current collaborative work requirements between the two Ranks. During the search, each key element in the first synchronization coordination information, such as the clock synchronization method, data transmission sequence, and data verification mechanism, should be compared one by one with the corresponding content of each entry in the table to find a matching entry. Once a matching first entry is found, its corresponding CHS mode is configured as the first CHS mode. This enables the LPDDR chip to perform synchronization coordination and data read-write operations between Ranks according to the rules specified by the accurate first CHS mode in the dual-Rank mode, ensuring that the two Ranks can work together efficiently and stably, meeting the system's data processing requirements for the LPDDR chip in dual-Rank application scenarios, ensuring the accurate transmission and storage of memory data, and improving the overall system's operating performance and reliability.

In some optional embodiments, when the first comparison result indicates that the second MR value has not been updated, the second MR value is corrected to the first MR value, and the second CHS mode is determined based on the second MR value. This process includes the following steps: when the first comparison result indicates that the second MR value has not been updated, configuring the LPDDR chip in single-Rank mode; correcting the second MR value to the first MR value based on the single-Rank mode so that the second MR value is equal to the first MR value; obtaining the second synchronization coordination table corresponding to the single-Rank mode; determining the second CHS mode based on the second synchronization coordination table and the second MR value.

Specifically, when the first comparison result indicates that the second MR value has not been updated, configuring the LPDDR chip in single-Rank mode is done. After determining to use the single-Rank mode, correcting the second MR value to the first MR value is to ensure consistency in the basic configurations of the two Ranks (although operating in single-Rank mode at this time, the concept of two Ranks still exists, with the second Rank being a virtual Rank). This allows the WCK-ON value determination method for dual-Rank LPDDR chips to be applicable to single-Rank LPDDR chips. The second synchronization coordination table corresponding to the single-Rank mode is a reference table specifically formulated for the chip operating in single-Rank mode. It records the correspondence between different MR values (the unified MR values after correction here) and the specific synchronization coordination modes (i.e., the second CHS mode) of the LPDDR chip in single-Rank mode, as well as relevant detailed parameter settings. This table covers multiple aspects such as the internal clock synchronization method within the single Rank (although there is no synchronization issue with another Rank, there are corresponding requirements for its own internal clock management), the coordination mechanism of data strobe signals (to ensure accurate data transmission and processing within this single Rank), and the requirements for the sequence and time intervals of read-write operations. It aims to provide comprehensive and accurate guidance for the LPDDR chip to achieve efficient and stable data processing in single-Rank mode, helping users quickly determine the appropriate synchronization coordination mode and related parameters based on the actual MR value situation.

After obtaining the second synchronization coordination table, it is necessary to determine the second CHS mode based on the currently corrected second MR value. First, parse each key information bit in the second MR value is parsed, as these information bits carry specific configuration details about the current single Rank (operating as a single Rank after configuration adjustment). For example, certain specific bits represent information such as the data transmission rate, the accuracy requirements for clock synchronization, or the priority of read-write operations. By extracting the meanings represented by these binary bits according to the interpretation method specified in the chip specifications, they are converted into specific configuration parameters. These key configuration parameters parsed out in the content of the second synchronization coordination table is mateched and searched. According to the correspondence specified in the table, when the corresponding record is found, the CHS mode corresponding to this record is the second CHS mode that needs to be determined. For example, the information parsed from the second MR value indicates that the data transmission rate is 1200 Mbps per second, clock synchronization adopts a relatively strict internal synchronization method, and read-write operations follow a write-before-read sequence. By searching for the corresponding entry in the second synchronization coordination table that meets these conditions, if the corresponding entry in the table shows that the second CHS mode corresponding to this situation is the "strict internal clock synchronization, write-before-read sequence, specific data strobe mechanism" mode, then this can be determined as the second CHS mode for the current situation. Subsequently, other key parameters such as the second WCK-ON value that are compatible with this determined second CHS mode can be further determined, ensuring that the chip can perform stable data read-write operations according to accurate synchronization coordination rules in single-Rank mode.

In some optional embodiments, determining the second CHS mode based on the second synchronization coordination table and the second MR value includes the following steps: determining second synchronization coordination information according to the second MR value and a preset configuration table; searching for a second entry in the second synchronization coordination table that matches the second synchronization coordination information; and configuring the CHS mode corresponding to the second entry as the second CHS mode.

Specifically, the second synchronization coordination table is formulated by LPDDR for the chip's single-Rank mode. It records the mapping relationships between various combinations of synchronization coordination information and corresponding CHS (Channel Synchronization) modes when the chip operates in single-Rank mode. The table encompasses different CHS modes corresponding to various parameter combinations, such as different data transmission rates, different clock synchronization methods, and various read-write sequences. It provides a reference for accurately determining the specific synchronization coordination mode of the chip in single-Rank mode. When searching for the second entry in the table that matches the second synchronization coordination information, it is necessary to compare each key element in the previously determined second synchronization coordination information, such as the data transmission rate, clock synchronization method, and read-write operation sequence, with the corresponding content of each entry in the table one by one. Once a matching second entry is accurately found in the second synchronization coordination table, its corresponding CHS mode is configured as the second CHS mode. This enables the LPDDR chip to perform internal data read-write operations, clock synchronization, and other operations in accordance with the rules specified by the accurate second CHS mode when operating in single-Rank mode. It ensures that data can be efficiently and stably transmitted and processed within this single Rank, preventing issues such as data errors and low read-write efficiency caused by improper synchronization coordination. It meets the system's requirements for determining the WCK-ON value of the LPDDR chip in single-Rank application scenarios, thereby ensuring the initialization accuracy of the single-Rank LPDDR chip.

Implementing the embodiments of the present disclosure offers the following beneficial effects. The embodiments of the present disclosure provide a method for determining the WCK-ON value of an LPDDR chip, which includes: obtaining the first MR value of the LPDDR chip, wherein the first MR value represents the first configuration information corresponding to the first Rank; obtaining the second MR value of the LPDDR chip, wherein the second MR value represents the second configuration information corresponding to the second Rank; comparing the first MR value and the second MR value with a preset MR value respectively to obtain a first comparison result; when the first comparison result indicates that the first MR value and/or the second MR value is equal to the preset MR value and the second MR value is updated, determining the first CHS mode based on the first MR value and the second MR value, and then determining the first WCK-ON value of the LPDDR chip based on the first CHS mode, wherein the first CHS mode indicates that the LPDDR chip has dual Ranks and the first synchronization coordination information between the Ranks; when the first comparison result indicates that the second MR value is not updated, correcting the second MR value to the first MR value, determining the second CHS mode based on the second MR value, and then determining the second WCK-ON value of the LPDDR chip based on the second CHS mode, wherein the second CHS mode indicates that the LPDDR chip has a single Rank and the second synchronization coordination information between the Ranks. By obtaining the first MR value and the second MR value of the first Rank and the second Rank and comparing them with the preset MR value, it can be determined whether the LPDDR chip has dual Ranks or a single Rank, and the corresponding first WCK-ON value and second WCK-ON value can be determined accordingly. This enables simultaneous compatibility with both dual-Rank and single-Rank LPDDR chips for determining the WCK-ON value, eliminating the need to formulate different initialization schemes for single-Rank and dual-Rank chips separately. It reduces testing costs, minimizes the error probability caused by scheme switching and other issues, and improves the accuracy of determining the WCK-ON value.

In a second aspect, referring to FIG. 3, the embodiments of the present disclosure provide a system for determining the WCK-ON value of an LPDDR chip, which includes:

a first module configued to obtain the first storage capacity of the LPDDR chip, wherein the first storage capacity represents the storage capacity corresponding to the first Rank;

a second module configued to obtain the second storage capacity of the LPDDR chip, wherein the second storage capacity represents the storage capacity corresponding to the second Rank;

a third module configued to compare the first storage capacity and the second storage capacity with a preset storage capacity respectively to obtain a first comparison result;

a fourth module configued to obtain the first EMI value and the second EMI value based on the first comparison result, a first storage table, and a second storage table, wherein the first storage table represents a relationship table between the first parameter value and the storage capacity, the second storage table represents a relationship table between the second parameter value and the storage capacity, the first EMI value represents the EMI value of the first Rank, and the second EMI value represents the EMI value of the second Rank;

a fifth module configued to determine the EMI value of the LPDDR chip based on the first EMI value and the second EMI value.

It is evident that the content in the above method embodiments is applicable to this system embodiment. The specific functions achieved by this system embodiment are the same as those in the above method embodiments, and the beneficial effects achieved are also the same.

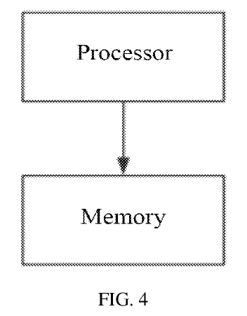

In a third aspect, referring to FIG. 4, the embodiments of the present disclosure provide a memory testing device, which includes:

at least one processor;

at least one memory for storing at least one program;

when the at least one program is executed by the at least one processor, it enables the at least one processor to implement the above method.

It is evident that the content in the above method embodiments is applicable to this device embodiment. The specific functions achieved by this device embodiment are the same as those in the above method embodiments, and the beneficial effects achieved are also the same.

In a fourth aspect, in addition, the embodiments of the present application also disclose a computer program product or computer program stored in a computer-readable storage medium. The processor of a computer device can read the computer program from the computer-readable storage medium, and the processor executes the computer program, enabling the computer device to perform the above method or the above system. Similarly, the content in the above method embodiments is applicable to this storage medium embodiment. The specific functions achieved by this storage medium embodiment are the same as those in the above method embodiments, and the beneficial effects achieved are also the same.

It can be understood that all or some of the steps and systems in the above-disclosed methods can be implemented as software, firmware, hardware, or an appropriate combination thereof. Some or all of the physical components can be implemented as software executed by a processor, such as a central processing unit, digital signal processor, or microprocessor, or as hardware, or as an integrated circuit, such as an application-specific integrated circuit. This software can be distributed on a computer-readable medium, which can include computer storage media (or non-transitory media) and communication media (or transitory media). As known to those skilled in the art, the term computer storage media includes volatile and non-volatile, removable and non-removable media implemented in any method or technology for storing information, such as computer-readable instructions, data structures, program modules, or other data. Computer storage media includes, but is not limited to, RAM, ROM, EEPROM, flash memory, or other memory technologies, CD-ROM, digital versatile disks (DVDs), or other optical disk storage, magnetic cassettes, magnetic tapes, magnetic disk storage, or other magnetic storage devices, or any other medium that can be used to store the desired information and can be accessed by a computer. Furthermore, as known to those skilled in the art, communication media typically contains computer-readable instructions, data structures, program modules, or other data in modulated data signals, such as carrier waves or other transmission mechanisms, and can include any information delivery media.

The above description, in conjunction with the accompanying drawings, provides a detailed explanation of the embodiments of the present disclosure. However, the present disclosure is not limited to the above embodiments. Within the scope of knowledge possessed by those skilled in the art, various changes can be made without departing from the purpose of the present disclosure.

1. A method for determining a WCK-ON value of an LPDDR chip, comprising:
obtaining a first MR value of the LPDDR chip, wherein the first MR value represents first configuration information corresponding to a first Rank;
obtaining a second MR value of the LPDDR chip, wherein the second MR value represents second configuration information corresponding to a second Rank;
comparing the first MR value and the second MR value respectively with a preset MR value to obtain a first comparison result;
determining a first CHS mode based on the first MR value and the second MR value when the first comparison result indicates that the first MR value and/or the second MR value is equal to the preset MR value and the second MR value is updated; and determining a first WCK-ON value of the LPDDR chip based on the first CHS mode, wherein the first CHS mode indicates that the LPDDR chip has a dual-Rank configuration and first synchronization coordination information between Ranks;
when the first comparison result indicates that the second MR value is not updated, modifying the second MR value to the first MR value, determining a second CHS mode based on the second MR value, and determining a second WCK-ON value of the LPDDR chip based on the second CHS mode, wherein the second CHS mode indicates that the LPDDR chip has a single-Rank configuration and second synchronization coordination information between Ranks.

2. The method according to claim 1, wherein the determining a first CHS mode based on the first MR value and the second MR value when the first comparison result indicates that the first MR value and/or the second MR value is equal to the preset MR value and the second MR value is updated, comprises:
when the first comparison result indicates that the first MR value is equal to the preset MR value, and/or the second MR value is equal to the preset MR value, and the second MR value is updated, configuring the LPDDR chip in a dual-Rank mode;
obtaining a first synchronization coordination table corresponding to the dual-Rank mode;
determining the first CHS mode based on the first synchronization coordination table, the first MR value, and the second MR value.

3. The method according to claim 2, wherein the determining the first CHS mode based on the first synchronization coordination table, the first MR value, and the second MR value, comprises:
determining the first configuration information and the second configuration information based on the first MR value, the second MR value, and a preset configuration table;
determining the first synchronization coordination information based on the first configuration information and the second configuration information;
searching for a first entry in the first synchronization coordination table that matches the first synchronization coordination information;
configuring the CHS mode corresponding to the first entry as the first CHS mode.

4. The method according to claim 1, wherein the method further comprises:
configuring the first CHS mode as a first mode when the first comparison result indicates that the first MR value is not equal to the preset MR value, the second MR value is not equal to the preset MR value, and the second MR value is updated; and configuring the first WCK-ON value as a first numerical value based on the first mode;
configuring the first CHS mode as a second mode when the first comparison result indicates that the first MR value and/or the second MR value is equal to the preset MR value and the second MR value is updated; and configuring the first WCK-ON value as a second numerical value based on the second mode.

5. The method according to claim 4, wherein determining the second CHS mode based on the second MR value and determining the second WCK-ON value of the LPDDR chip based on the second CHS mode, comprises:
configuring the second CHS mode as the second mode when the second MR value is equal to the preset MR value; and configuring the second WCK-ON value as the second numerical value based on the second mode;
configuring the second CHS mode as the first mode when the second MR value is not equal to the preset MR value; and configuring the second WCK-ON value as the first numerical value based on the first mode.

6. The method according to claim 1, wherein modifying the second MR value to the first MR value when the first comparison result indicates that the second MR value is not updated and determining the second CHS mode based on the second MR value, comprises:
configuring the LPDDR chip in a single-Rank mode when the first comparison result indicates that the second MR value is not updated;
modifying the second MR value to the first MR value based on the single-Rank mode so that the second MR value is equal to the first MR value;
obtaining a second synchronization coordination table corresponding to the single-Rank mode;
determining the second CHS mode based on the second synchronization coordination table and the second MR value.

7. The method according to claim 6, wherein the determining the second CHS mode based on the second synchronization coordination table and the second MR value, comprises:
determining the second synchronization coordination information based on the second MR value and a preset configuration table;
searching for a second entry in the second synchronization coordination table that matches the second synchronization coordination information;
configuring the CHS mode corresponding to the second entry as the second CHS mode.

8. A system for determining a WCK-ON value of an LPDDR chip, comprising:
a first module configured to obtain a first MR value of the LPDDR chip, wherein the first MR value represents first configuration information corresponding to a first Rank;
a second module configured to obtain a second MR value of the LPDDR chip, wherein the second MR value represents second configuration information corresponding to a second Rank;
a third module configured to compare the first MR value and the second MR value respectively with a preset MR value to obtain a first comparison result;
a fourth module configured to, when the first comparison result indicates that the first MR value and/or the second MR value is equal to the preset MR value and the second MR value is updated, determine a first CHS mode based on the first MR value and the second MR value, and determine a first WCK-ON value of the LPDDR chip based on the first CHS mode, wherein the first CHS mode indicates that the LPDDR chip has a dual-Rank configuration and first synchronization coordination information between Ranks;
a fifth module configured to, when the first comparison result indicates that the second MR value is not updated, modify the second MR value to the first MR value, determine a second CHS mode based on the second MR value, and determine a second WCK-ON value of the LPDDR chip based on the second CHS mode, wherein the second CHS mode indicates that the LPDDR chip has a single-Rank configuration and second synchronization coordination information between Ranks.

9. A memory testing device, comprising:
at least one processor;
at least one memory configured to store at least one program;
when the at least one program is executed by the at least one processor, the at least one processor is caused to implement the method according to claim 1.
